(19) United States
(12) Patent Application Publication
(10) Pub. No.: US 2025/0221218 A1
(43) Pub. Date: Jul. 3, 2025

(54) DISPLAY DEVICE

(71) Applicant: LG Display Co., Ltd., Seoul (KR)

(72) Inventors: HeeJung HONG, Seoul (KR); Binn KIM, Seoul (KR)

(21) Appl. No.: 18/809,057

(22) Filed: Aug. 19, 2024

(30) Foreign Application Priority Data
Dec. 28, 2023 (KR) 10-2023-0195333

(51) Int. Cl. H10K 59/35; H10K 59/121; H10K 59/131

(52) U.S. Cl. CPC H10K 59/351; H10K 59/1213; H10K 59/131; H10K 59/353

(57) ABSTRACT

A display device and a display control method are disclosed according to the present disclosure, the display device includes a substrate and a plurality of pixels which is defined on the substrate and is configured to operate in an emission mode or a transparent mode. Each of the plurality of pixels includes a plurality of sub pixels and a transmissive area, a plurality of pixels which is adjacent to each other in a first direction, among the plurality of pixels, is disposed such that each transmissive area is adjacent to each other, the plurality of sub pixels includes a first sub pixel, a second sub pixel, a third sub pixel, and a fourth sub pixel which emits white light. Further, the fourth sub pixel is disposed so as to be adjacent to one side of the first sub pixel, the second sub pixel, and the third sub pixel.

### CROSS-REFERENCE TO RELATED APPLICATIONS

This application claims the priority of Korean Patent Application No. 10-2023-0195333 filed on Dec. 28, 2023, in the Korean Intellectual Property Office, the disclosure of which is incorporated herein by reference.

### BACKGROUND

### Technical Field

The present disclosure relates to a display device, and more particularly, to a display device which improves a transmissive area and improves an image clump of adjacent pixels.

### Description of the Related Art

As display devices which are used for a monitor of a computer, a television, or a cellular phone, there are an organic light emitting display (OLED) device, which is a self-emitting device and a liquid crystal display (LCD) device, which requires a separate light source.

An applicable range of the display device is diversified to personal digital assistants as well as monitors of computers and televisions and a display device with a large display area and a reduced volume and weight is being studied.

Recently, studies on a transparent display device are being actively conducted. The transparent display device refers to a display device which allows a user to recognize not only visual information implemented on a display panel from a front surface of the panel, but also objects located on a rear surface of the display panel. To this end, the transparent display device includes an emission area in which driving elements are disposed to implement an input image and a transmissive area through which external light is transmitted.

### BRIEF SUMMARY

The inventors of the present disclosure have appreciated that in order to allow the user to more clearly see background information located on the rear surface of the display panel of the transparent display device, it is beneficial to ensure a sufficient area occupied by the transmissive area. Various embodiments of the present disclosure address the shortcomings of the transparent display device in the related art. Various embodiments further addresses one or more technical problems in the related art including the above-identified problem.

Various embodiments of the present disclosure provide a display device in which transmissive areas are disposed to be adjacent to each other in a plurality of pixels adjacent in the left and right to improve a transmissive area, thereby improving a see-through characteristic which recognizes an object located on a rear surface of the display panel.

Various embodiments of the present disclosure provide a display device which improves an image clump of a plurality of pixels which is adjacent to each other in the left and right.

Various embodiments of the present disclosure provide an algorithm which improves a representation of vertical lines in a plurality of pixels adjacent to each other in the left and right when white light or gray light is emitted.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate; and a plurality of pixels which is defined on the substrate and is configured to operate in an emission mode or a transparent mode. Each of the plurality of pixels includes a plurality of sub pixels and a transmissive area. A plurality of pixels which is adjacent to each other in a first direction, among the plurality of pixels, is disposed such that each transmissive area is adjacent to each other. The plurality of sub pixels includes a first sub pixel which emits first color light, a second sub pixel which emits second color light, a third sub pixel which emits third color light, and a fourth sub pixel which emits white light. Further, the first sub pixel, the second sub pixel, and the third sub pixel are disposed side by side in a second direction which intersects the first direction, and the fourth sub pixel is disposed so as to be adjacent to one side of the first sub pixel, the second sub pixel, and the third sub pixel.

Other detailed matters of the exemplary embodiments are included in the detailed description and the drawings.

According to the present disclosure, transmissive areas are disposed to be adjacent to each other in a plurality of pixels adjacent in the left and right to improve a transmissive area, thereby improving a see-through characteristic which recognizes an object located on a rear surface of the display panel.

According to an exemplary embodiment of the present disclosure, a first sub pixel, a second sub pixel, and a third sub pixel included in each of the plurality of pixels are disposed side by side in a vertical direction. A fourth sub pixel which emits white light is disposed to be adjacent to one side of the first sub pixel, the second sub pixel, and the third sub pixel. Therefore, there is an interval between the plurality of pixels which is adjacent to each other in the left and right by the fourth sub pixel so that an image quality degradation problem caused by disposing the plurality of sub pixels to be adjacent to each other may be improved.

According to the exemplary embodiment of the present disclosure, when white light or gray light is emitted, the first sub pixel, the second sub pixel, and the third sub pixel which are disposed with an interval by the fourth sub pixel emit light first to emit white light or gray light. Therefore, degradation of the vertical representation caused by disposing the fourth sub pixel which emits white light to be adjacent in the plurality of pixels which is adjacent to each other in the left and right may be improved.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2 is a plan view of one pixel according to an exemplary embodiment of the present disclosure;

FIG. 3 is a schematic plan view of a plurality of pixels according to an exemplary embodiment of the present disclosure;

FIG. 4A is a diagram illustrating white light emission by a fourth sub pixel, among a plurality of pixels according to an exemplary embodiment of the present disclosure;

FIG. 4B is a diagram illustrating white light emission by first, second, and third sub pixels among a plurality of pixels according to an exemplary embodiment of the present disclosure;

FIG. 5 is an equivalent circuit diagram of each of a plurality of pixels according to an exemplary embodiment of the present disclosure;

FIG. 6A is an enlarged plan view illustrating a plurality of adjacent pixels of a display device according to an exemplary embodiment of the present disclosure;

FIG. 6B is an enlarged plan view illustrating a plurality of adjacent pixels of a display device according to an exemplary embodiment of the present disclosure;

FIG. 7 is a cross-sectional view taken along VII-VII′ of FIG. 6B; and

FIG. 8 is a schematic plan view of a plurality of pixels according to another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

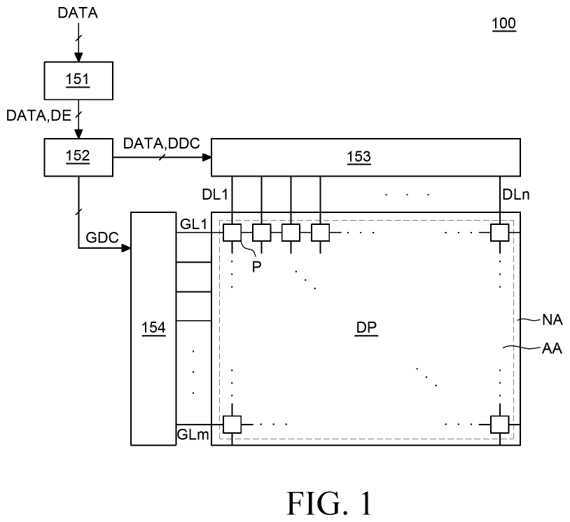

FIG. 1 is a block diagram of a display device 100 according to an exemplary embodiment of the present disclosure.

In the display device 100 according to the exemplary embodiment of the present disclosure, at least a partial area of a screen of the display device 100 which is visible to a viewer may be a transparent display device 100. For example, in the present disclosure, the display device 100 may be a display device 100 which has a transparency enough to allow a user to recognize an object on at least the rear surface of the display device 100. For example, the display device 100 of the present disclosure has a light transmittance of at least 40% or higher.

Referring to FIG. 1, a display device 100 according to an exemplary embodiment of the present disclosure may include an image processor 151, a timing controller 152, a data driver 153, a gate driver 154, and a display panel DP.

At this time, the image processor 151 may output a data signal DATA supplied from the outside and a data enable signal DE. The image processor 151 may output one or more of a vertical synchronization signal, a horizontal synchronization signal, and a clock signal in addition to the data enable signal DE.

The timing controller 152 is supplied with the data signal DATA together with a driving signal including the data enable signal DE or the vertical synchronization signal, the horizontal synchronization signal, and the clock signal, from the image processor 151. The timing controller 152 may output a gate timing control signal GDC for controlling an operation timing of the gate driver 154 and a data timing control signal DDC for controlling an operation timing of the data driver 153, based on the driving signal.

Further, the data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn.

Further, the gate driver 154 may output the gate signal while shifting a level of the gate voltage, in response to the gate timing control signal GDC supplied from the timing controller 152. The gate driver 154 may output the gate signal through gate lines GL1 to GLm.

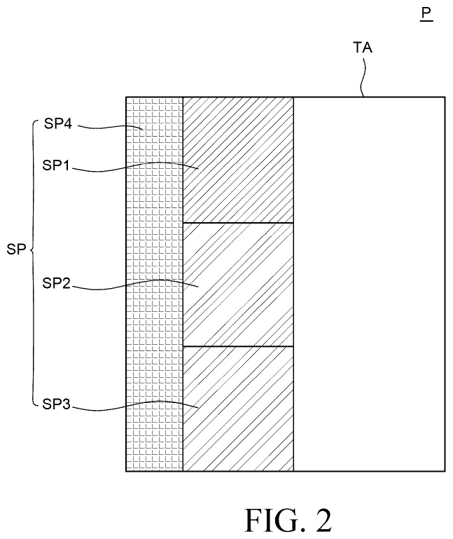

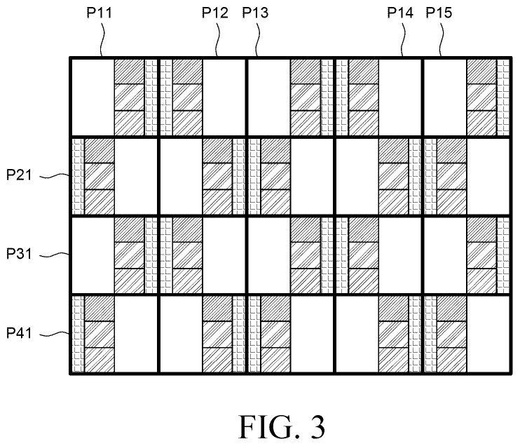

The display panel DP may display images while a pixel P emits light in response to the data signal DATA and the gate signal supplied from the data driver 153 and the gate driver 154. A detailed structure of the pixel P will be described in detail with reference to FIGS. 2 and 3.

The display panel DP may include an active area AA and a non-active area NA. The active area AA is an area where images are displayed in the display panel DP.

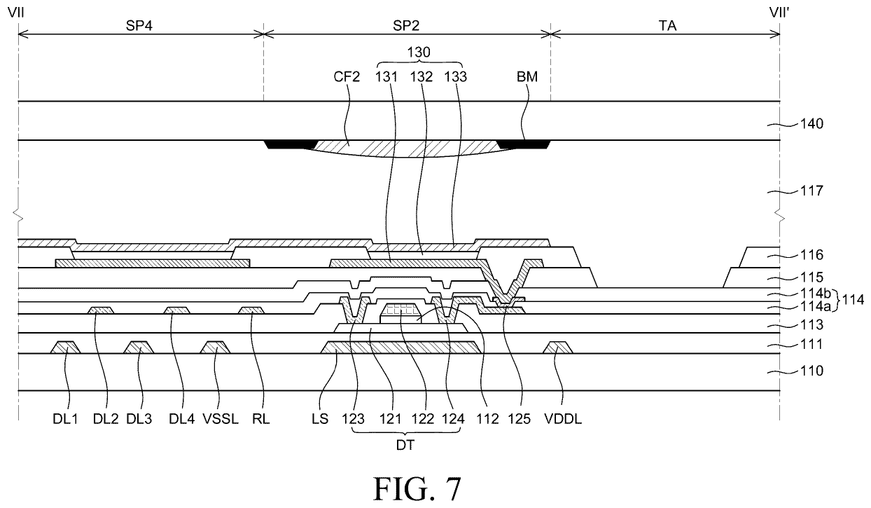

In the active area AA, a plurality of pixels P and a circuit for driving the plurality of pixels may be disposed. The plurality of pixels P may be disposed in a matrix on the substrate 110 (for example, see FIG. 7) of the display panel DP, but is not limited thererto. The plurality of pixels P is a minimum unit which configures the active area AA and a display element may be disposed in each of the plurality of pixels P. For example, an organic light emitting diode which includes an anode, an emission layer, and a cathode may be disposed in each of the plurality of pixels P, but it is not limited thereto. Further, a circuit for driving the plurality of pixels P may include a driving element and a wiring line. For example, the circuit may be configured by a thin film transistor, a storage capacitor, a gate line, and a data line, but is not limited thereto.

The non-active area NA is an area where no image is displayed.

The non-active area NA is bent so as not to be seen from a front surface or blocked by a case (not illustrated) and is also referred to as a bezel area.

Even though in FIG. 1, it is illustrated that the non-active area NA encloses a quadrangular active area AA, shapes and placements of the active area AA and the non-active area NA are not limited to the example illustrated in FIG. 1. That is, the active area AA and the non-active area NA may have shapes suitable for a design of an electronic device including the device 100. For example, an exemplary shape of the active area AA may be a pentagon, a hexagon, a circle, or an oval.

In the non-active area NA, various wiring lines, circuits, and the like for driving the organic light emitting diode of the active area AA are disposed. For example, in the non-active area NA, a link line which transmits signals to the plurality of pixels and circuits of the active area AA, a gate-in-panel (GIP) line, or a driving IC, such as a gate driver 154 or a data driver 153, may be disposed, but it is not limited thereto.

The display device 100 may further include various additional elements to generate various signals or drive the pixel in the active area AA. The additional elements for driving the pixels may include an inverter circuit, a multiplexer, an electrostatic discharge (ESD) circuit, or the like. The display device 100 may further include an additional element associated with a function other than a function of driving a pixel. For example, the display device 100 may include additional elements which provide a touch sensing function, a user authentication function (for example, fingerprint recognition), a multilevel pressure sensing function, a tactile feedback function, or the like. The above-mentioned additional elements may be located in an external circuit which is connected to the non-active area NA and/or the connecting interface.

Hereinafter, the pixel P of the present disclosure will be described in more detail with reference to FIGS. 2 and 3 together.

FIG. 2 is a plan view of one pixel according to an exemplary embodiment of the present disclosure. FIG. 3 is a schematic plan view of a plurality of pixels according to an exemplary embodiment of the present disclosure.

Referring to FIGS. 2 and 3, each of the plurality of pixels P according to the exemplary embodiment of the present disclosure includes a plurality of sub pixels SP and a transmissive area TA. The plurality of pixels P may include a plurality of pixels P11, P12, P13, P14, and P15 disposed in a first direction (an x-axis direction) and a plurality of pixels P11, P21, P31, and P41 disposed in a second direction (a y-axis direction), for example, in a matrix.

The plurality of sub pixels SP may be a basic emission unit which configures the display device 100. Each of the plurality of sub pixels SP may be an element for representing one color. A plurality of sub pixels SP which configures one pixel P may include a first sub pixel SP1, a second sub pixel SP2, a third sub pixel SP3, and a fourth sub pixel SP4 which emit different color light. For example, the plurality of sub pixels SP may include a first sub pixel SP1 which emits first color light, a second sub pixel SP2 which emits second color light, a third sub pixel SP3 which emits third color light, and a fourth sub pixel SP4 which emit white light. For example, the first sub pixel SP1 is a red sub pixel, the second sub pixel SP2 is a green sub pixel, the third sub pixel SP3 is a blue sub pixel, and the fourth sub pixel SP4 may be a white sub pixel.

The transmissive area TA may be defined as an area where external light is transmitted to allow a user to recognize an object located on a rear surface of the display device. Further, the transmissive area TA may be defined as an area in which signal lines are not disposed. However, when a signal line is implemented with a transparent material to have a predetermined transparency, the signal line is disposed also in the transmissive area TA, but it is not limited thereto.

According to the exemplary embodiment of the present disclosure, a plurality of pixels P11, P12, P13, P14, and P15 which is adjacent to each other in the first direction (for example, the x-axis direction), among the plurality of pixels P, may be disposed such that transmissive areas TA are adjacent to each other (for example, in FIG. 3, the transmissive areas TA of pixels P12 and P13 are adjacent to each other. In other words, at least a portion of the adjacent pixels are adjacent to each other in the manner that their transmission areas TA are adjacent to each other). Therefore, the transmissive area is expanded so that the see-through characteristic which allows an object located on the rear surface of the display panel to be visible may be improved.

According to the exemplary embodiment of the present disclosure, the plurality of pixels P11, P12, P13, P14, and P15 which is adjacent to each other in the first direction (for example, the x-axis direction), among the plurality of pixels P, is disposed such that the transmissive areas TA are adjacent to each other. Therefore, the plurality of pixels P11, P12, P13, P14, and P15 which is adjacent to each other in the first direction (for example, the x-axis direction), among the plurality of pixels P, may be also disposed such that the sub pixels SP are adjacent to each other.

For example, when first, second, and third sub pixels SP1, SP2, and SP3 of one pixel P11, among the plurality of pixels P11, P12, P13, P14, and P15 which is adjacent to each other in the first direction (for example, the x-axis direction), which emit first color light, second color light, and third color light and first, second, and third sub pixels SP1, SP2, and SP3 of another pixel P12 which is adjacent to one pixel P11 in the first direction (x-axis direction) are disposed to be adjacent to each other, the images between adjacent pixels are clumped. Therefore, it is difficult to distinguish a vertical line so that an image quality problem, such as resolution degradation, may occur.

Therefore, according to the exemplary embodiment of the present disclosure, at least one fourth sub pixel SP4 may be disposed between first, second, and third sub pixels SP1, SP2, and SP3 of one pixel P11, among the plurality of pixels P which is adjacent to each other in the first direction (for example, the x-axis direction) and first, second, and third sub pixels SP1, SP2, and SP3 of another pixel P12 which is adjacent to one pixel P11 in the first direction (x-axis direction).

For example, the first sub pixel SP1, the second sub pixel SP2, and the third sub pixel SP3 may be disposed side by side in the second direction (for example, a y-axis direction) intersecting the first direction (x-axis direction). At this time, the fourth sub pixel SP4 may be disposed to be adjacent to one side of each of the first sub pixel SP1, the second sub pixel SP2, and the third sub pixel SP3 (as shown in FIG. 2).

Further, referring to FIG. 3 together, according to the exemplary embodiment of the present disclosure, a plurality of sub pixels SP of each of the plurality of pixels P11, P12, P13, P14, and P15 which is adjacent to each other in the first direction (the x-axis direction), among the plurality of pixels P, is disposed to be adjacent to each other. In some embodiments, at least one fourth sub pixel SP4 may be disposed between first, second, and third sub pixels SP1, SP2, and SP3 of one pixel P11, among the plurality of pixels P which is adjacent to each other in the first direction (the x-axis direction) and first, second, and third sub pixels SP1, SP2, and SP3 of another pixel P12 which is adjacent to one pixel P11 in the first direction (x-axis direction). For example, a fourth sub pixel SP4 of one pixel P11, among the plurality of pixels P11, P12, P13, P14, and P15 which is adjacent to each other in the first direction, among the plurality of pixels P, is disposed to be adjacent to, for example, to be in contact with a fourth sub pixel SP4 of another pixel P12 adjacent to one pixel P11 in the first direction (x-axis direction).

Accordingly, the first, second, and third sub pixels SP1, SP2, and SP3, of a plurality of sub pixels SP included in each of the plurality of pixels P which is adjacent to each other in the first direction (the x-axis direction), which emit first color light, second color light, and third color light are not in direct contact with the first, second, and third sub pixels SP1, SP2, and SP3 of the sub-pixel SP of the adjacent pixel, but maintain a constant interval by at least one fourth sub pixel SP4 disposed therebetween. Therefore, the image clump may be improved by improving the vertical line distinction between adjacent pixels P and the degradation of the image quality may be suppressed.

According to the exemplary embodiment of the present discourse, fourth sub pixels SP4 of at least a portion of the plurality of pixels P11, P12, P13, P14, and P15 which is adjacent to each other in the first direction (such as pixels P11 and P12 adjacent to each other in the first direction as shown in FIG. 3), among the plurality of pixels P, are disposed to be adjacent to each other. At this time, the image clump when the first color light, the second color light, and the third color light are emitted may be improved. However, image clump issue may occur when the white light or gray light is emitted.

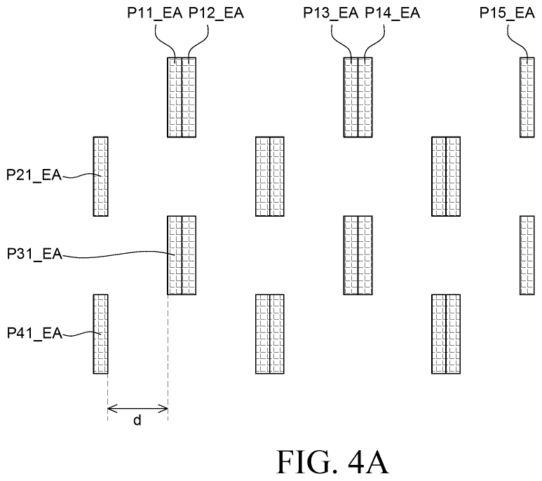

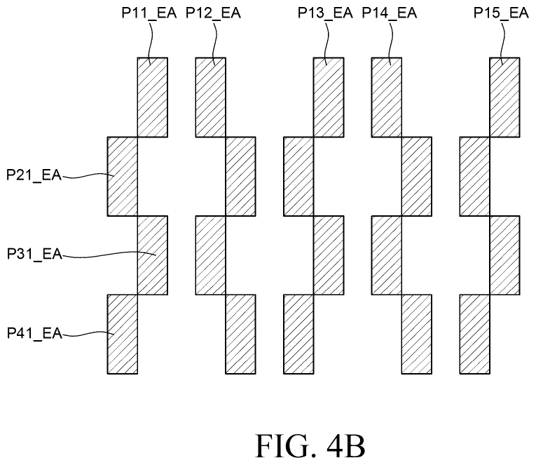

Hereinafter, an algorithm when white light or gray light is emitted will be described with reference to FIGS. 4A and 4B.

FIG. 4A is a diagram illustrating white light emission by a fourth sub pixel SP4, among a plurality of pixels P according to an exemplary embodiment of the present disclosure. FIG. 4B illustrates white light emission by first, second, and third sub pixels SP1, SP2, and SP3 among a plurality of pixels P according to an exemplary embodiment of the present disclosure.

Referring to FIG. 4A, when white light is emitted using the fourth sub pixel SP4, due to an interval d in the first direction (as shown in FIG. 3) between emission areas P11_EA, P21_EA, P31_EA, P41_EA of the fourth sub pixels SP4 which emit white light, in the plurality of pixels P11, P21, P31, P41, . . . which is disposed to be adjacent to each other in the second direction (y-axis direction), the plurality of pixels which is disposed to be adjacent to each other in the second direction is not recognized as one line, but is recognized as a plurality of lines. Accordingly, when the white light or the gray light is emitted, the visibility is lowered.

Further, when the white light is emitted using the fourth sub pixel SP4, if the emission areas P11_EA, P12_EA, P13_EA, P14_EA of the fourth sub pixels SP4 which emit white light, in the plurality of pixels P11, P12, P13, P14, . . . which is disposed to be adjacent to each other in the first direction (x-axis direction), are disposed to be adjacent to each other (for example, P11_EA and P12_EA), images are clumped by the fourth sub pixels SP4 which are adjacent to each other. Therefore, it is difficult to distinguish the vertical line, which causes the image quality degradation.

Therefore, according to the exemplary embodiment of the present disclosure, when the white light or the gray light is emitted, the white light or gray light is emitted not by the fourth sub pixel SP4, but by the first, second, and third sub pixels SP1, SP2 and SP3 so that the image quality degradation problem may be improved even when the white light or the gray light is emitted.

Referring to FIG. 4B, in a plurality of pixels P11, P21, P31, and P41 which is adjacent to each other in the second direction (y-axis direction), among the plurality of pixels P according to the exemplary embodiment of the present disclosure, a plurality of sub pixels SP and the transmissive areas TA may be alternately disposed.

According to the exemplary embodiment of the present disclosure, in the plurality of pixels P11, P21, P31, and P41 which is adjacent to each other in the second direction (y-axis direction), among the plurality of pixels P, the transmissive area TA may be disposed to be adjacent to the first sub pixel SP1, the second sub pixel SP2, and the third sub pixel SP3 which are disposed side by side in the second direction (y-axis direction). That is, the first, second, and third sub pixels SP1, SP2, and SP3 of one pixel P11, among the plurality of pixels P11, P21, P31, and P41 which is adjacent to each other in the second direction (y-axis direction), among the plurality of pixels P and the first, second, and third sub pixels SP1, SP2, and SP3 of another pixel P21 which is adjacent to one pixel P11 in the second direction (y-axis direction) may be disposed in the zigzag form. For example, the first, second, and third sub pixels SP1, SP2, and SP3 of one pixel P11, among the plurality of pixels P11, P21, P31, and P41 which is adjacent to each other in the second direction (y-axis direction), among the plurality of pixels P and the first, second, and third sub pixels SP1, SP2, and SP3 of another pixel P21 which is adjacent to one pixel P11 in the second direction (y-axis direction) are disposed with a zigzag pattern while sharing one vertex, but the present disclosure is not limited thereto.

According to one exemplary embodiment, when the white light is emitted using the first, second, and third sub pixels SP1, SP2, and SP3, an interval between areas P11_EA, P21_EA, P31_EA, and P41_EA which emit white light in the plurality of pixels P11, P21, P31, P41, . . . disposed to be adjacent to each other in the second direction (y-axis direction) is narrow. Therefore, when the white light is emitted, the plurality of pixels which is disposed to be adjacent to each other in the second direction may be recognized as one line. Accordingly, when the white light or the gray light is emitted, the visibility may be improved.

Further, when the white light is emitted using the first, second, and third sub pixels SP1, SP2, and SP3, the emission areas P11_EA, P12_EA, P13_EA, P14_EA, and P15_EA which emit white light in the plurality of pixels P11, P12, P13, P14, . . . which is disposed to be adjacent to each other in the first direction (x-axis direction) are not in direct contact with each other. However, the constant interval is maintained by at least one fourth sub pixel SP4 so that even though the white light or the gray light is emitted, the vertical line distinction between adjacent pixels P is improved to improve the image clump and suppress the image quality degradation thereby.

Further, according to the exemplary embodiment of the present disclosure, when the white light or the gray light is emitted, the white light or the gray light is implemented by the first, second, and third sub pixels SP1, SP2, and SP3. Thereafter, in order to improve the luminance, the fourth sub pixel SP4 may further emit light. In this case, as compared with the case that the white light or the gray light is emitted only using the first, second, and third sub pixels SP1, SP2, SP3, the vertical line distinction may be lowered, but the luminance may be further improved. Therefore, the high dynamic range (HDR) may be implemented or a panel edge portion may be implemented. Accordingly, when the white light or the gray light is emitted, only the first, second, and third sub pixels SP1, SP2, and SP3 are used or if necessary, all the first, second, third, and fourth sub pixels SP1, SP2, SP3, and SP4 may be used.

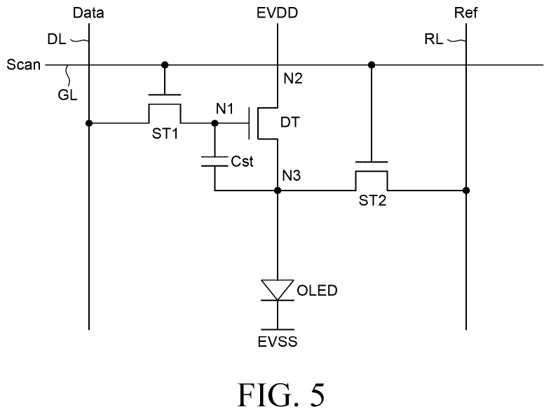

Hereinafter, a structure of a plurality of pixels P of the present disclosure will be described in more detail with reference to FIGS. 5 to 7.

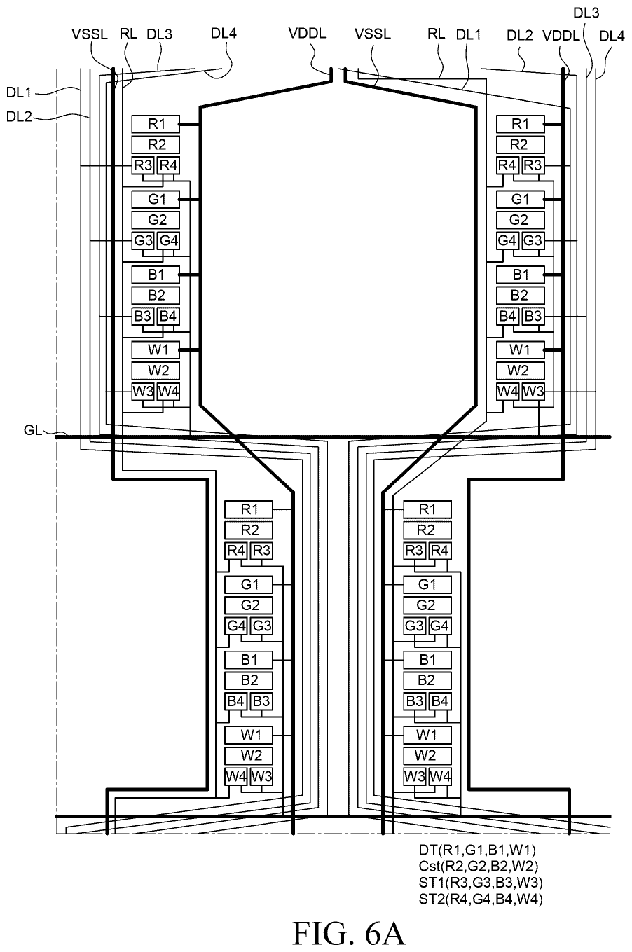

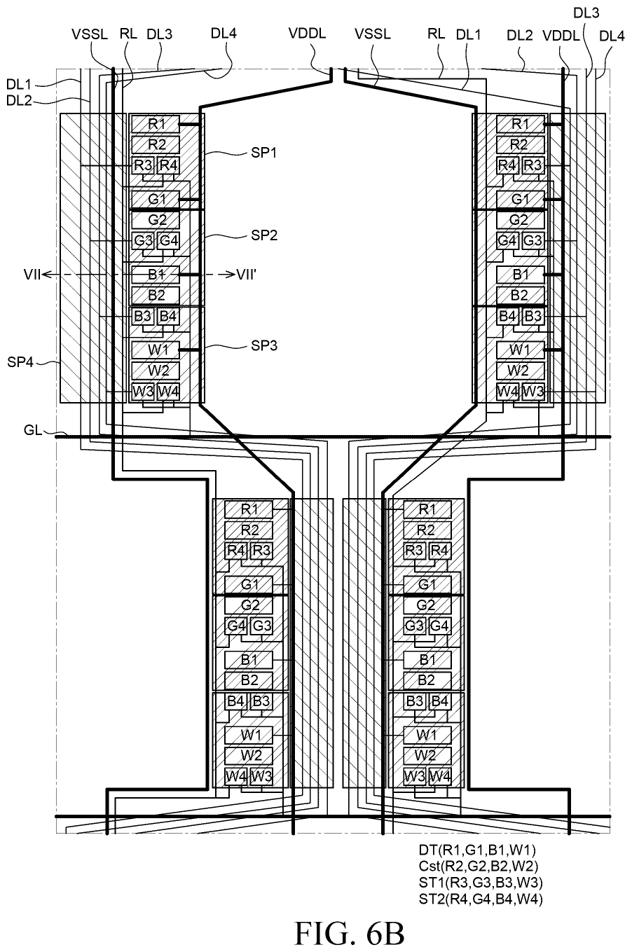

FIG. 5 is an equivalent circuit diagram of each of a plurality of pixels P according to an exemplary embodiment of the present disclosure. FIG. 6A is an enlarged plan view illustrating a plurality of adjacent pixels of a display device according to an exemplary embodiment of the present disclosure. FIG. 6B is an enlarged plan view illustrating a plurality of adjacent pixels of a display device according to an exemplary embodiment of the present disclosure. FIG. 7 is a cross-sectional view taken along the line VII-VII′ of FIG. 6B.

Referring to FIGS. 5 and 6A, each of the plurality of sub pixels SP is connected to a plurality of wiring lines. The plurality of wiring lines includes a data line DL to which a data voltage DATA is supplied, a reference voltage line RL to which a reference voltage Ref is supplied, a pixel power line VDDL which applies a pixel driving voltage EVDD, and a gate line GL to which a scan signal SCAN is supplied. The scan signal SCAN is a signal which swings between a gate high voltage VGH and a gate low voltage VGL.

The plurality of sub pixels SP is configured to include a light emitting diode OLED, a driving transistor DT, a first switching transistor ST1, a second switching transistor ST2, and a storage capacitor Cst.

The light emitting diode OLED is configured to include organic compound layers formed between an anode and a cathode. The organic compound layer includes a hole injection layer HIL, a hole transport layer HTL, an emission layer EML, an electron transport layer ETL, and an electron injection layer EIL, but it is not limited thereto. The light emitting diode OLED is a light emitting diode which is connected between a third node N3 which is connected to a source electrode of the driving transistor DT and the low potential driving power EVSS and emits light according to the driving current. The light emitting diode OLED is configured to represent red, green, blue, or white.

The plurality of pixels P may be located in an area where the data line DL and the gate line GL intersect. For example, the gate line GL extends in the first direction (x-axis direction) and the data line DL may extend in the second direction (y-axis direction) which intersects the first direction.

The reference voltage line RL and the pixel power line VDDL which are connected to the plurality of pixels P may extend in the second direction (y-axis direction) which is parallel to the data line DL. For example, the data line DL, the reference voltage line RL, and the pixel power line VDDL connected to each of the plurality of pixels P may be disposed so as to overlap at least a part of the plurality of sub pixels SP1, SP2, SP3, and SP4.

According to the exemplary embodiment of the present disclosure, the plurality of pixels P includes a plurality of sub pixels SP and transmissive areas TA. The plurality of pixels P adjacent to each other in the first direction (x-axis direction), among the plurality of pixels P, may be disposed such that the transmissive areas TA are adjacent to each other. Referring to FIG. 3 together, a part of the plurality of pixels P may be disposed such that in two pixels (for example, P12 and P13) which are adjacent to each other in the first direction (x-axis direction), sub pixels SP are opposite to each other with two transmissive areas TA therebetween.

Further, the other of the plurality of pixels P may be disposed such that in two pixels (for example, P13 and P14) which are adjacent to each other in the first direction (x-axis direction), transmissive areas are opposite to each other with sub pixels SP therebetween.

In a plurality of pixels P11, P21, P31, and P41 which is adjacent to each other in the second direction (y-axis direction), among the plurality of pixels P, a plurality of sub pixels SP and the transmissive areas TA may be alternately disposed. That is, the pixels which are adjacent to each other in the second direction (y-axis direction) may be disposed such that pixels with the transmissive area therebetween like P12 and P13 of FIG. 3 or with the sub pixels therebetween like P13 and P14 of FIG. 3, may be alternately disposed to avoid the sub-pixels SP of pixels adjacent to each other in the second direction from being aligned with each other along the second direction.

According to the exemplary embodiment of the present disclosure, in accordance with the above-described pixel P disposition, the data line DL, the reference voltage line RL, and the pixel power line VDDL connected to the plurality of pixels P in the second direction (y-axis direction) may change the shape and the position according to the position.

For example, referring to FIG. 6A, two pixels P which are adjacent to each other in the first direction (x-axis direction), among the plurality of pixels P, are disposed such that sub pixels SP are opposite to each other with two transmissive areas TA therebetween. At this time, wiring lines connected to the plurality of sub pixels SP1, SP2, SP3, and SP4 with respect to the transmissive area TA in the second direction (y-axis direction) may be disposed to be symmetric to each other. For example, the data line DL, the reference voltage line RL, and the pixel power line VDDL are disposed so as to overlap at least a part of the plurality of sub pixels SP1, SP2, SP3, and SP4. Therefore, the data line DL, the reference voltage line RL, and the pixel power line VDDL may be disposed to be the farthest away from two adjacent pixels P. At this time, two pixels P which are adjacent to each other in the first direction (x-axis direction), among the plurality of pixels P, are symmetric to each other with respect to the transmissive area TA so that wiring lines disposed with respect to the transmissive area TA are also symmetrically formed. However, the disposition order of the wiring lines is the same for each pixel P so that the same wiring lines may not be symmetrically formed. For example, the plurality of wiring lines connected to each pixel P in the second direction (y-axis direction) may be disposed in the order of the common voltage line VSSL, the reference voltage line RL, and the pixel power line VDDL. However, a plurality of data lines DL is configured by a first data line DL1 connected to the first sub pixel SP1, a second data line DL2 connected to the second sub pixel SP2, a third data line DL3 connected to the third sub pixel SP3, and a fourth data line DLA connected to the fourth sub pixel SP4. Accordingly, when the plurality of wiring lines is disposed, the first data line DL1, the second data line DL2, the third data line DL3, and the fourth data line DL4 may be separately disposed between the common voltage line VSSL, the reference voltage line RL, and the pixel power line VDDL, but it is not limited thereto.

For example, referring to FIG. 6A, two pixels P which are adjacent to each other in the first direction (x-axis direction), among the plurality of pixels P, are disposed such that the transmissive areas TA are opposite to each other with two sub pixels SP therebetween. At this time, wiring lines connected to the plurality of sub pixels SP1, SP2, SP3, and SP4 in the second direction (y-axis direction) may be disposed to be symmetric to each other. For example, the data line DL, the reference voltage line RL, and the pixel power line VDDL are disposed so as to overlap at least a part of the plurality of sub pixels SP1, SP2, SP3, and SP4 so that the data line DL, the reference voltage line RL, and the pixel power line VDDL are also disposed to be adjacent in two adjacent pixels P. At this time, two pixels P which are adjacent to each other in the first direction (x-axis direction), among the plurality of pixels P, are symmetric to each other with respect to the sub pixels SP so that wiring lines disposed with respect to the sub pixels SP are also symmetrically formed. However, the disposition order of the wiring lines is the same for each pixel P so that the same wiring lines are not symmetrically formed.

As illustrated in FIG. 6A, in the plurality of pixels P, two pixels P which are adjacent to each other in the first direction (x-axis direction) may be disposed with the transmissive area TA therebetween (as shown in the upper portion of FIG. 6A). In the plurality of pixels P adjacent to this pixel in the second direction (y-axis direction), two pixels P adjacent to each other in the first direction (x-axis direction) may be disposed with the sub pixels SP therebetween. Accordingly, the plurality of wiring lines connected to the plurality of pixels P in the second direction (y-axis direction) is also alternately disposed in the second direction (y-axis direction) so as to overlap the sub pixels SP (as shown in the lower portion of FIG. 6A). For example, the plurality of wiring lines extended and connected to the plurality of pixels P in the second direction (y-axis direction) may be disposed with a zigzag pattern in the second direction (y-axis direction) so as to overlap the sub pixels SP.

The driving transistor DT includes a gate electrode connected to a first node N1, a drain electrode connected to a second node N2, and a source electrode connected to a third node N3. The driving transistor DT drives the light emitting diode OLED by adjusting a current amount applied to the light emitting diode OLED according to a gate-source voltage. The pixel power line VDDL which applies a pixel driving voltage EVDD may be applied to the drain electrode of the driving transistor DT.

The first switching transistor ST1 includes a gate electrode connected to the gate line GL, a drain electrode connected to the data line DL, and a source electrode connected to the first node N1. The first switching transistor ST1 is turned on in response to a scan signal SCAN from the gate line GL. When the first switching transistor ST1 is turned on, a data line DL to which the data voltage DATA is applied is electrically connected to the first node N1 to apply the data voltage DATA to the gate electrode of the driving transistor DT and the storage capacitor Cst.

The second switching transistor ST2 includes a gate electrode connected to the gate line GL, a drain electrode connected to the reference voltage line RL, and a source electrode connected to the third node N3. The second switching transistor ST2 is turned on in response to the scan signal SCAN from the gate line GL to electrically connect the reference voltage line RL and the third node N3 to apply the reference voltage Ref to the third node N3. The reference voltage Ref is set to be lower than the pixel driving voltage EVDD. In the meantime, when it is necessary to sense an electrical characteristic of the driving transistor DT, the second switching transistor ST2 is turned on. In this case, a sensing signal from the gate driver 154 is applied to the gate electrode of the second switching transistor ST2. For example, the sensing signal controls a timing to turn off the timing when the first switching transistor ST1 is turned on and turn on the timing when the first switching transistor ST1 is turned off, but the control of the sensing signal is not limited to the timing control.

The storage capacitor Cst is connected between the first node N1 and the third node N3 to maintain the gate-source voltage Vgs of the driving transistor DT during an emission period. The higher the gate-source voltage Vgs, the higher the driving current so that the emission amount of the pixel P is increased. In other words, the luminance of the pixel P may increase in proportion to a magnitude of a voltage which is applied to the first node N1, that is, the data voltage DATA.

The sub pixel illustrated in FIG. 5 is configured with a 3T (transistor) 1C (capacitor) structure including a first switching transistor ST1, a second switching transistor ST2, a driving transistor DT, a capacitor Cst, and a light emitting diode OLED, but may also be configured with various structures, such as 4T2C, 5T2C, 6TIC, 6T2C, 7T1C, and 7T2C, but it is not limited thereto.

FIG. 6B illustrates an area in which first, second, third, and fourth sub pixels SP1, SP2, SP3, and SP4 are disposed in an enlarged plan view illustrating a plurality of adjacent pixels of the display device of FIG. 6A.

Referring to FIG. 6B, according to the exemplary embodiment of the present disclosure, each of the plurality of pixels P includes a plurality of thin film transistors DT1, ST1, and ST2 and a plurality of light emitting diodes OLED. The plurality of thin film transistors DT1, ST1, and ST2 is disposed so as to overlap the first sub pixel SP1, the second sub pixel SP2, and the third sub pixel SP3 which are disposed side by side in the second direction (y-axis direction). The plurality of light emitting diodes OLED is electrically connected to the plurality of thin film transistors DT, ST1, and ST2.

Further, a plurality of wiring lines is disposed so as to overlap the fourth sub pixel SP4. The plurality of the plurality of thin film transistors DT1, ST1, and ST2 which drives the fourth sub pixel SP4 may be disposed so as to overlap the first sub pixel SP1, the second sub pixel SP2, and the third sub pixel SP3 which are disposed side by side in the second direction (y-axis direction).

Referring to FIG. 7 together, the display device 100 according to the exemplary embodiment of the present disclosure includes a substrate 110, a plurality of transistors DT, and a plurality of light emitting diodes 130. In the substrate, a plurality of pixels P including a plurality of sub pixels SP1 to SP4 and a transmissive area TA is defined. The plurality of transistors DT is disposed so as to overlap the first, second, and third sub pixels SP1, SP2, and SP3. The plurality of light emitting diodes 130 is electrically connected to the plurality of transistors.

The substrate 110 is a component for supporting various components included in the display device 100 and may be formed of an insulating material. For example, the substrate 110 may be a glass substrate or a plastic substrate. For example, the plastic substrate may be selected from polyimide, polyethersulfone, polyethylene terephthalate, polyetherimide, polymethylmethacrylate, and polycarbonate, but is not limited thereto.

A light shielding layer LS is disposed on the substrate 110 so as to overlap a channel region of the driving transistor DT. The light shielding layer LS may be disposed not only below the channel region of the driving transistor DT, but also below channel regions of the first and second switching transistors ST1 and ST2. The light shielding layer LS may be formed of a conductive material and for example, may be formed by a single layer or a multilayer formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

Further, at least one of the plurality of wiring lines may be provided on the same layer as the light shielding layer LS. For example, the first data line DL1 connected to the first sub pixel SP1, the third data line DL3 connected to the third sub pixel SP3, the common power line VSSL, and the pixel power line VDDL are disposed on the same layer with the same material as the light shielding layer LS, but are not limited thereto.

A buffer layer 111 is disposed on the substrate 110. The buffer layer 111 is a layer for protecting the driving transistor DT from impurities such as alkali ions leaked from the substrate 110 or layers therebelow. The buffer layer 111 may be formed of silicon oxide (SiOx), silicon nitride (SiNx), or a double layer thereof.

The driving transistor DT is disposed on the buffer layer 111.

The driving transistor DT includes an active layer 121, a gate electrode 122, a source electrode 123, and a drain electrode 124. For example, the active layer 121 is formed on the substrate 110 and the gate insulating layer 112 which insulates the gate electrode 122 from the active layer 121 is disposed on the active layer 121 and the substrate 110. The gate electrode 122 is formed on the gate insulating layer 112 and the source electrode 123 and the drain electrode 124 are formed on the active layer 121 and the gate insulating layer 112. The source electrode 123 and the drain electrode 124 may be in contact with the active layer 121 to be electrically connected to the active layer 121. In the present specification, for the convenience of description, among various thin film transistors which may be included in the light emitting display device 100, only a driving element is illustrated, but a switching element may also be included. Further, in the present specification, even though it is described that the driving element DT has a coplanar structure, an inverted staggered thin film transistor may also be used.

To be more specific, the active layer 121 is disposed on the buffer layer 111. The active layer 121 may be formed of amorphous silicon (a-Si), polycrystalline silicon (poly-Si), an oxide semiconductor, or an organic semiconductor. When the active layer 121 is formed of oxide semiconductor, the active layer may be formed of indium gallium zinc oxide (IGZO), but it is not limited thereto.

The gate insulating layer 112 is disposed on the active layer 121. The gate insulating layer 112 insulates the active layer 121 from the gate electrode 122. The gate insulating layer 112 may be formed as a single layer of silicon nitride (SiNx) or silicon oxide (SiOx) which is an inorganic material or a multilayer of silicon nitride (SiNx) and silicon oxide (SiOx), but it is not limited thereto.

The gate electrode 122 is disposed on the gate insulating layer 112. The gate electrode 122 may be formed of a conductive material such as titanium (Ti), copper (Cu), aluminum (Al), molybdenum (Mo), or an alloy thereof, but is not limited thereto.

An interlayer insulating layer 113 is disposed on the gate electrode 122. The interlayer insulating layer 113 may be configured by a single layer of silicon nitride (SiNx) or silicon oxide (SiOx) or a multilayer thereof. A contact hole through which the source region and the drain region of the active layer 121 of the driving transistor DT are exposed may be formed in the interlayer insulating layer 113.

A source electrode 123 and a drain electrode 124 are disposed on the interlayer insulating layer 113. The source electrode 123 and the drain electrode 124 are electrically connected to the active layer 121 through a contact hole formed in the interlayer insulating layer 113. The source electrode 123 and the drain electrode 124 may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

A first passivation layer 114a may be disposed on the source electrode 123 and the drain electrode 124. The first passivation layer 114a is provided to protect the driving transistor DT and may be formed of an inorganic film, for example, silicon oxide (SiOx), silicon nitride (SiNx), or a double layer thereof.

Further, at least one of the plurality of wiring lines may be provided on the same layer as the source electrode 123 and the drain electrode 124. For example, the second data line DL2 connected to the second sub pixel SP2, the fourth data line DL4 connected to the fourth sub pixel SP4, and the reference voltage line RL are disposed on the same layer with the same material as the source electrode 123 and the drain electrode 124, but are not limited thereto.

The connection electrode 125 may be disposed on the first passivation layer 114a. The connection electrode 125 may be electrically connected to the drain electrode 124 of the driving transistor DT through a contact hole provided in the first passivation layer 114a.

A second passivation layer 114b is located on the connection electrode 125.

An over coating layer 115 is located on the second passivation layer 114b. The over coating layer 115 protects the driving transistor DT and planarizes an upper portion thereof.

An anode 131 which is electrically connected to the driving transistor DT may be disposed on the over coating layer 115.

At this time, the anode 131 may be connected to the connection electrode 125 which is electrically connected to the drain electrode 124 of the driving transistor DT through a contact hole provided in the over coating layer 115 and the passivation layer 114. The anode 131 may be formed of a metallic material.

When the display device 100 is a top emission type in which light emitted from the light emitting diode (OLED) 130 is emitted above the substrate 110 in which the light emitting diode (OLED) 130 is disposed, the anode 131 may further include a transparent conductive layer and a reflective layer on the transparent conductor layer. The transparent conductive layer may be formed of transparent conductive oxide such as ITO or IZO and the reflective layer is formed of silver (Ag), aluminum (Al), gold (Au), molybdenum (Mo), tungsten (W), chrome (Cr), or an alloy thereof.

The bank 116 may be disposed while covering the anode 131. A part of the bank 116 corresponding to an emission area of the sub pixel may be open. A part of the anode 131 may be exposed through the open part of the bank 116 (hereinafter, referred to as an open area). At this time, the bank 116 may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

The emission layer 132 may be disposed in the open area of the bank 116 and in the vicinity of the open area of the bank. Therefore, the emission layer 132 may be disposed on the anode 131 exposed through the open area of the bank 116.

The cathode 133 may be disposed on the emission layer 132. The cathode 133 supplies electrons to the emission layer 132 so that the cathode may be formed of a conductive material having a low work function.

The light emitting diode (OLED) 130 may be formed by the anode 131, the emission layer 132, and the cathode 133. The emission layer 132 may include a plurality of organic layers.

An encapsulation unit 117 may be disposed above the cathode 133. The encapsulation unit 117 serves to suppress permeation of oxygen or moisture to the emission layer 132 and the cathode 133. To this end, the encapsulation unit 117 may include at least one inorganic film and at least one organic film.

For example, the inorganic film which is included in the encapsulation unit 117 may be configured by silicon nitride (SiNx), silicon oxide (SiOx), silicon oxynitride (SiON), or aluminum oxide Al₂O₃, but it is not limited thereto.

For example, the organic film included in the encapsulation unit 117 may serve to enhance the planarization performance and may be configured by an organic insulating material, such as acrylic resin, epoxy resin, polyimide, polyethylene, silicon oxy carbon (SiOC), but it is not limited thereto.

A color filter CF is disposed on the encapsulation unit 117. The color filter CF may be provided on one surface of the cover glass 140 which is opposite to the substrate 110. In this case, the substrate 110 with the light emitting diode 130 and the cover glass 140 with the color filter CF may be bonded by a separate adhesive layer. At this time, the adhesive layer (not illustrated) is an optically clear resin layer (OCR) or an optically clear adhesive film (OCA), but is not limited thereto.

For example, a color of each sub pixels SP may be implemented by a color filter CF which is disposed above the driving transistor DT so as to overlap the emission area of the sub pixel SP. For example, the color filter CF includes a first color filter CF1, a second color filter CF2, and a third color filter CF3 which are separated so as to correspond to the first sub pixel SP1, the second sub pixel SP2, and the third sub pixel SP3 and are located on the same plane.

For example, when the light emitting diode 130 emits first red light, a red color filter CF1 is disposed in an area corresponding to the emission area of the light emitting diode 130 to implement a red sub pixel SP1. The first color filter CF1 may be a red color filter which is disposed so as to correspond to an emission area of the first sub pixel SP1 and transmits red light. The second color filter CF2 may be a green color filter which is disposed so as to correspond to an emission area of the second sub pixel SP2 and transmits green light. The third color filter CF3 may be a blue color filter which is disposed so as to correspond to an emission area of the third sub pixel SP3 and transmits blue light. In the meantime, a color filter may not be disposed in an emission area of the fourth sub pixel SP4.

In the meantime, a black matrix BM may be provided between color filters CF and between a color filter CF and a transmissive area TA. The black matrix BM is provided between the sub pixels SP1, SP2, SP3, and SP4 to suppress color mixture generated between adjacent sub pixels SP1, SP2, SP3, and SP4. Further, the black matrix BM is provided between the transmissive area TA and the plurality of sub pixels SP1, SP2, SP3, and SP4 to suppress light emitted from each of the plurality of sub pixels SP1, SP2, SP3, and SP4 from traveling to the transmissive area TA.

For example, the black matrix BM may include a material which absorbs light, for example, a black dye which absorbs all light in a wavelength band of a visible ray, but is not limited thereto.

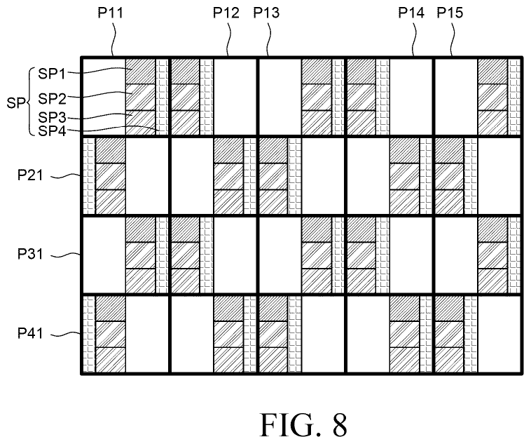

Hereinafter, a display device according to another exemplary embodiment of the present disclosure will be described in detail with reference to FIG. 8.

FIG. 8 is a schematic plan view of a plurality of pixels according to another exemplary embodiment of the present disclosure. A plurality of pixel structures of a display device illustrated in FIG. 8 is substantially the same as the plurality of pixel structures of the display device illustrated in FIG. 3 except a position of the fourth sub pixel SP4. Therefore, for the convenience of description, among the plurality of pixel structures, a redundant description excluding a position relationship of the first sub pixel SP1, the second sub pixel SP2, and the third sub pixel SP3 and the fourth sub pixel SP4 will be omitted.

According to the exemplary embodiment of the present disclosure, a plurality of pixels P which is adjacent to each other in the first direction (for example, the x-axis direction), among the plurality of pixels SP, may be disposed such that transmissive areas TA are adjacent to each other. Therefore, the transmissive area is expanded so that the see-through characteristic which allows an object located on the rear surface of the display panel to be visible may be improved.

According to the exemplary embodiment of the present disclosure, the plurality of pixels P11, P12, P13, P14, and P15 which is adjacent to each other in the first direction (for example, the x-axis direction), among the plurality of pixels P, is disposed such that the transmissive areas TA are adjacent to each other. Therefore, the plurality of pixels P11, P12, P13, P14, and P15 which is adjacent to each other in the first direction (for example, the x-axis direction), among the plurality of pixels P, may be also disposed such that the sub pixels SP are adjacent to each other.

For example, when among a plurality of sub pixels SP of each of the plurality of pixels P11, P12, P13, P14, and P15 which is adjacent to each other in the first direction (the x-axis direction), first, second, and third sub pixels SP1, SP2, and SP3 which emit first, second, and third color light are disposed to be adjacent to each other, images between the adjacent pixels are clumped to make it difficult to distinguish the vertical line. Therefore, an image quality problem, such as degradation of resolution may be caused.

Therefore, according to the exemplary embodiment of the present disclosure, at least one fourth sub pixel SP4 may be disposed between the plurality of pixels P11, P12, P13, P14, and P15 which is adjacent to each other in the first direction (the x-axis direction), among the plurality of pixels P.

For example, the first sub pixel SP1, the second sub pixel SP2, and the third sub pixel SP3 may be disposed side by side in the second direction (for example, a y-axis direction) intersecting the first direction (x-axis direction). At this time, the fourth sub pixel SP4 may be disposed to be adjacent to one side of each of the first sub pixel SP1, the second sub pixel SP2, and the third sub pixel SP3.

Specifically, according to the exemplary embodiment of the present disclosure, the plurality of sub pixels SP of each of the plurality of pixels P11, P12, P13, P14, and P15 which is adjacent to each other in the first direction (the x-axis direction), among the plurality of pixels P, is disposed to be adjacent to each other. At this time, in the plurality of sub pixels SP, the first sub pixel SP1, the second sub pixel SP2, and the third sub pixel SP3 which are disposed side by side in the second direction (for example, a y-axis direction) and the fourth sub pixel SP4 which is disposed to be adjacent to one side thereof may be alternately disposed.

Accordingly, the first, second, and third sub pixels SP1, SP2, and SP3, of the plurality of sub pixels SP included in each of the plurality of pixels P which is adjacent to each other in the first direction (the x-axis direction), which emit first, second, and third color light are not in direct contact with each other, but maintain a predetermined interval by the fourth sub pixel SP4. Therefore, the image clump is improved and image quality degradation is suppressed by improving the vertical line distinction between adjacent pixels P.

The exemplary embodiments of the present disclosure can also be described as follows:

According to an aspect of the present disclosure, a display device, comprises a substrate, and a plurality of pixels which is defined on the substrate and is configured to operate in an emission mode or a transparent mode, each of the plurality of pixels includes a plurality of sub pixels and a transmissive area, a plurality of pixels which is adjacent to each other in a first direction, among the plurality of pixels, is disposed such that each transmissive area is adjacent to each other, the plurality of sub pixels includes a first sub pixel which emits first color light, a second sub pixel which emits second color light, a third sub pixel which emits third color light, and a fourth sub pixel which emits white light, the first sub pixel, the second sub pixel, and the third sub pixel are disposed side by side in a second direction which intersects the first direction, and the fourth sub pixels is disposed so as to be adjacent to one side of the first sub pixel, the second sub pixel, and the third sub pixel.

A plurality of sub pixels of each of a plurality of pixels which is adjacent to each other in the first direction, among the plurality of pixels, is disposed so as to be adjacent to each other, and the fourth sub pixel may be disposed between the first sub pixel, the second sub pixel, and the third sub pixel which are included in each of the plurality of pixels and are disposed side by side in the second direction.

A plurality of sub pixels of each of a plurality of pixels which is adjacent to each other in the first direction, among the plurality of pixels, is disposed so as to be adjacent to each other, and the first sub pixel, the second sub pixel, and the third sub pixel which are included in each of the plurality of pixels and are disposed side by side in the second direction and the fourth sub pixel may be alternately disposed.

The fourth sub pixel of each of a plurality of pixels which is adjacent to each other in the first direction, among the plurality of pixels, may be disposed so as to be adjacent to each other.

In a plurality of pixels which are adjacent to each other in the second direction, among the plurality of pixels, the plurality of sub pixels and the transmissive area may be alternately disposed.

The transmissive area in the plurality of pixels which are adjacent to each other in the second direction, among the plurality of pixels, may be disposed to be adjacent to the first sub pixel, the second sub pixel, and the third sub pixel which are disposed side by side in the second direction.

The first sub pixel, the second sub pixel, and the third sub pixel, of one pixel among a plurality of pixels which is adjacent to each other in the second direction, among the plurality of pixels, which are disposed side by side in the second direction may be disposed to form a zigzag pattern with the first sub pixel, the second sub pixel, and the third sub pixel, of another pixel, which are disposed side by side in the second direction.

In the emission mode of the plurality of pixels, when white light or gray light is emitted, all the first sub pixel, the second sub pixel, and the third sub pixel may emit light.

In the emission mode of the plurality of pixels, when white light or gray light is emitted, the fourth sub pixel may further emit light.

The plurality of pixels may include a plurality of thin film transistors which is disposed so as to overlap the first sub pixel, the second sub pixel, and the third sub pixel disposed side by side in the second direction and a plurality of light emitting diodes which is electrically connected to the plurality of thin film transistors.

The display device may further comprise a plurality of wiring lines which is disposed so as to overlap the fourth sub pixel, a thin film transistor which drives the fourth sub pixel is disposed so as to overlap the first sub pixel, the second sub pixel, and the third sub pixel disposed side by side in the second direction.

According to another aspect of the present disclosure, a display control method for controlling the display device according to the first aspect, the control method comprising: when white light or gray light needs to be emitted, controlling all of the first sub-pixels, the second sub-pixels and the third sub-pixels to emit light.

The display control method may further comprises, when the luminance of the emitted white light or gray light emitted needs to be improved, controlling the fourth sub-pixel to further emit light; or when the luminance of the emitted white light or gray light needs to be reduced and the first sub-pixel, the second sub-pixel, the third sub-pixel and the fourth sub-pixel are all emitting light, controlling the fourth sub-pixel to stop emitting light.

According to a third aspect of the present disclosure, a display device, comprising:
a substrate; and a plurality of pixels which is defined on the substrate and each of the pixels includes a plurality of sub pixels and a transmissive area, wherein an adjacent pixel group including a first pixel and a second pixel adjacent to each other in a first direction, the respective transmissive area of the first pixel and the second pixel are adjacent to each other, the adjacent pixel groups are repeatedly arranged in the first direction and in a second direction intersecting the first direction, and the adjacent pixel groups adjacent to each other in the second direction are staggered by an interval of one pixel, and the plurality of sub pixels includes a first sub pixel which emits first color light, a second sub pixel which emits second color light, a third sub pixel which emits third color light, and a fourth sub pixel which emits white light, the first sub pixel, the second sub pixel, and the third sub pixel are disposed side by side in a second direction which intersects the first direction, and the fourth sub pixel is disposed so as to be adjacent to one side of the first sub pixel, the second sub pixel, and the third sub pixel.

Preferably, the display device according to the third aspect, wherein the fourth sub-pixel of the first pixel is located at the leftmost side of the adjacent pixel group, and the fourth sub-pixel of the second pixel is located at the rightmost side of the adjacent pixel group.

Preferably, the display device according to the third aspect, wherein the fourth sub-pixel of the first pixel is located on the left side of the transmissive area of the first pixel, and the fourth sub-pixel of the second pixel is located on the rightmost side of the adjacent pixel group.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate; and
a plurality of pixels on the substrate and is configured to operate in an emission mode or a transparent mode,
wherein each of the plurality of pixels includes a plurality of sub pixels and a transmissive area adjacent to the plurality of sub pixels,
wherein the plurality of pixels is adjacent to each other in a first direction,
wherein the plurality of sub pixels includes a first sub pixel which emits first color light, a second sub pixel which emits second color light, a third sub pixel which emits third color light, and a fourth sub pixel which emits white light,
wherein the first sub pixel, the second sub pixel, and the third sub pixel are disposed side by side in a second direction transverse to the first direction, and
wherein the fourth sub pixel is disposed to be adjacent to one side of the first sub pixel, the second sub pixel, and the third sub pixel.

2. The display device according to claim 1, wherein a plurality of sub pixels of each of a plurality of pixels which is adjacent to each other in the first direction, among the plurality of pixels, are disposed to be adjacent to a plurality of sub pixels of an adjacent pixel.

3. The display device according to claim 2,
wherein the first sub pixel, the second sub pixel, and the third sub pixel included in each of the pixels adjacent to each other disposed side by side in the second direction and the fourth sub pixel are alternately disposed.

4. The display device according to claim 2, wherein the fourth sub pixel of each of a plurality of pixels which is adjacent to each other in the first direction, among the plurality of pixels, is disposed to be adjacent to a fourth sub pixel of an adjacent pixel.

5. The display device according to claim 1, wherein in a plurality of pixels which are adjacent to each other in the second direction, among the plurality of pixels, the plurality of sub pixels and the transmissive area are alternately disposed along the second direction.

6. The display device according to claim 5, wherein the transmissive area in each of the plurality of pixels which are adjacent to each other in the second direction, among the plurality of pixels, is disposed to be adjacent to the first sub pixel, the second sub pixel, and the third sub pixel which are disposed side by side in the second direction.

7. The display device according to claim 6, wherein the first sub pixel, the second sub pixel, and the third sub pixel, of one pixel among a plurality of pixels which is adjacent to each other in the second direction, among the plurality of pixels, which are disposed side by side in the second direction are disposed to form a zigzag pattern with the first sub pixel, the second sub pixel, and the third sub pixel, of the adjacent pixel, which are disposed side by side in the second direction.

8. The display device according to claim 7, wherein in the emission mode of the plurality of pixels, when white light or gray light is emitted, all the first sub pixel, the second sub pixel, and the third sub pixel emit light.

9. The display device according to claim 8, wherein in the emission mode of the plurality of pixels, when white light or gray light is emitted, the fourth sub pixel further emits light.

10. The display device according to claim 1, wherein the plurality of pixels includes a plurality of thin film transistors which is disposed to overlap the first sub pixel, the second sub pixel, and the third sub pixel disposed side by side in the second direction and a plurality of light emitting diodes which is electrically connected to the plurality of thin film transistors.

11. The display device according to claim 10, further comprising:
a plurality of wiring lines which is disposed to overlap the fourth sub pixel,
wherein a thin film transistor which drives the fourth sub pixel is disposed to overlap the first sub pixel, the second sub pixel, and the third sub pixel disposed side by side in the second direction.

12. The display device according to claim 10, further comprising: a plurality of wiring lines having a predetermined transparency, wherein the plurality of wiring lines are arranged in at least a portion of the transmissive area.

13. A display control method for controlling the display device of any one of claims 1 to 12, the display control method comprising:
when white light or gray light needs to be emitted, controlling all of the first sub-pixels, the second sub-pixels and the third sub-pixels to emit light.

14. The display control method according to claim 13, further comprising:
controlling the fourth sub-pixel to further emit light.

15. A display device, comprising:
a substrate; and
a plurality of pixels which are defined on the substrate and each of the pixels includes a plurality of sub pixels and a transmissive area,
wherein an adjacent pixel group including a first pixel and a second pixel adjacent to each other in a first direction, the respective transmissive area of the first pixel and the second pixel are adjacent to each other, the adjacent pixel groups are repeatedly arranged in the first direction and in a second direction intersecting the first direction, and the adjacent pixel groups adjacent to each other in the second direction are staggered by an interval of one pixel, and
the plurality of sub pixels includes a first sub pixel which emits first color light, a second sub pixel which emits second color light, a third sub pixel which emits third color light, and a fourth sub pixel which emits white light,
the first sub pixel, the second sub pixel, and the third sub pixel are disposed side by side in a second direction which intersects the first direction, and
the fourth sub pixel is disposed so as to be adjacent to one side of the first sub pixel, the second sub pixel, and the third sub pixel.

16. The display device according to claim 15, wherein the fourth sub-pixel of the first pixel is located at the leftmost side of the adjacent pixel group, and the fourth sub-pixel of the second pixel is located at the rightmost side of the adjacent pixel group.

17. The display device according to claim 15, wherein the fourth sub-pixel of the first pixel is located on the left side of the transmissive area of the first pixel, and the fourth sub-pixel of the second pixel is located on the rightmost side of the adjacent pixel group.
